(19) United States
(12) Patent Application Publication
(10) Pub. No.: US 2013/0234330 A1
(43) Pub. Date: Sep. 12, 2013

(54) Semiconductor Packages and Methods of Formation Thereof

(71) Applicant: Horst Theuss, Wenzenbach (DE)

(72) Inventor: Horst Theuss, Wenzenbach (DE)

(73) Assignee: Infineon Technologies AG, Neubiberg (DE)

(21) Appl. No.: 13/415,356

(22) Filed: Mar. 8, 2012

(51) Int. Cl. H01L 23/482; H01L 21/56; H01L 21/60

(52) U.S. Cl. 257/741; 257/777; 438/107; 438/124; 257/E23.017; 257/E23.012; 257/E21.506; 257/E21.502

(57) ABSTRACT

In one embodiment, a method of forming a semiconductor package includes applying a film layer having through openings over a carrier and attaching a back side of a semiconductor chip to the film layer. The semiconductor chip has contacts on a front side. The method includes using a first common deposition and patterning step to form a conductive material within the openings. The conductive material contacts the contacts of the semiconductor chip. A reconfigured wafer is formed by encapsulating the semiconductor chip, the film layer, and the conductive material in an encapsulant using a second common deposition and patterning step. The reconfigured wafer is singulated to form a plurality of packages.

### TECHNICAL FIELD

The present invention relates generally to a semiconductor devices, and more particularly to semiconductor packages and methods of formation thereof.

### BACKGROUND

Semiconductor devices are used in many electronic and other applications. Semiconductor devices comprise integrated circuits or discrete devices that are formed on semiconductor wafers by depositing many types of thin films of material over the semiconductor wafers, and patterning the thin films of material to form the integrated circuits.

The semiconductor devices are typically packaged within a ceramic or a plastic body to protect from physical damage and corrosion. The packaging also supports the electrical contacts required to connect to the devices. Many different types of packaging are available depending on the type and the intended use of the die being packaged. Typical packaging, e.g., dimensions of the package, pin count, may comply with open standards such as from Joint Electron Devices Engineering Council (JEDEC). Packaging may also be referred as semiconductor device assembly or simply assembly.

Packaging may be a cost intensive process because of the complexity of connecting multiple electrical connections to external pads while protecting these electrical connections and the underlying chips.

### SUMMARY OF THE INVENTION

These and other problems are generally solved or circumvented, and technical advantages are generally achieved, by illustrative embodiments of the present invention.

In one embodiment, a method of forming a semiconductor package includes applying a film layer having through openings over a carrier and attaching a back side of a semiconductor chip to the film layer. The semiconductor chip has contacts on a front side. The method includes using a first common deposition and patterning step to form a conductive material within the openings. The conductive material contacts the contacts of the semiconductor chip. A reconfigured wafer is formed by encapsulating the semiconductor chip, the film layer, and the conductive material in an encapsulant using a second common deposition and patterning step. The reconfigured wafer is singulated to form a plurality of packages.

The foregoing has outlined rather broadly the features of an embodiment of the present invention in order that the detailed description of the invention that follows may be better understood. Additional features and advantages of embodiments of the invention will be described hereinafter, which form the subject of the claims of the invention. It should be appreciated by those skilled in the art that the conception and specific embodiments disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawing, in which:

FIG. 1 illustrates a cross-sectional view of a semiconductor device formed using embodiments of the invention;

FIG. 2, which includes FIGS. 2A and 2B, illustrates a semiconductor package during fabrication after forming a film layer over a carrier in accordance with an embodiment of the invention, wherein FIG. 2A illustrates a cross-sectional view and FIG. 2B illustrates a top view;

FIG. 3, which includes FIGS. 3A and 3B, illustrates a semiconductor package during fabrication after attaching dies over a film layer in accordance with an embodiment of the invention, wherein FIG. 3A illustrates a cross-sectional view and wherein FIG. 3B illustrates a top view;

FIG. 4, which includes FIGS. 4A and 4B, illustrates a semiconductor package during fabrication after forming through vias and/or conductive lines in accordance with an embodiment of the invention, wherein FIG. 4A illustrates a cross-sectional view and wherein FIG. 4B illustrates a top view;

FIG. 5 illustrates a cross-sectional view of a semiconductor package during fabrication after encapsulating the dies in accordance with an embodiment of the invention;

FIG. 6, which includes FIGS. 6A and 6B, illustrates a semiconductor package after singulating the reconfigured wafer in accordance with an embodiment of the invention, wherein FIG. 6A illustrates a cross-sectional view and wherein FIG. 6B illustrates a bottom view;

FIG. 7, which includes FIGS. 7A and 7B, illustrates a semiconductor package during fabrication after forming a film layer over a carrier in accordance with an alternative embodiment of the invention, wherein FIG. 7A illustrates a cross-sectional view and wherein FIG. 7B illustrates a magnified top view;

FIG. 8, which includes FIGS. 8A and 8B, illustrates a semiconductor package during fabrication after attaching dies over the film layer in accordance with an alternative embodiment of the invention, wherein FIG. 8A illustrates a cross-sectional view and wherein FIG. 8B illustrates a top view;

FIG. 9, which includes FIGS. 9A and 9B, illustrates a semiconductor package during fabrication after forming through vias and/or conductive lines in accordance with an alternative embodiment of the invention, wherein FIG. 9A illustrates a cross-sectional view and wherein FIG. 9B illustrates a top view;

FIG. 10, which includes FIGS. 10A and 10B, illustrates a semiconductor package during fabrication after encapsulating the dies in accordance with an alternative embodiment of the invention, wherein FIG. 10A illustrates a cross-sectional view and wherein FIG. 10B illustrates a top view;

FIG. 11, which includes FIGS. 11A and 11B, illustrates a semiconductor package after dicing the reconfigured wafer in accordance with an alternative embodiment of the invention, wherein FIG. 11A illustrates a cross-sectional view, wherein FIG. 11B illustrates a bottom view, and wherein FIG. 11C illustrates a top view;

FIGS. 12-16 illustrate an alternative embodiment of forming a semiconductor package comprising multiple chips during fabrication;

FIG. 17, which includes FIGS. 17A-17C, illustrates semiconductor packages formed using embodiments of the invention; and

FIG. 18, which includes FIGS. 18A-18D, illustrates semiconductor packages formed using embodiments of the invention and mounted over a circuit board.

Corresponding numerals and symbols in the different figures generally refer to corresponding parts unless otherwise indicated. The figures are drawn to clearly illustrate the relevant aspects of the embodiments and are not necessarily drawn to scale.

### DETAILED DESCRIPTION OF ILLUSTRATIVE EMBODIMENTS

The making and using of various embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

In various embodiments, the present invention teaches forming semiconductor packages using very low cost processes thereby dramatically reducing the cost of packaging semiconductor devices. As will be described in detail, in various embodiments, as much as possible, multiple process steps are combined in to a single process step to reduce manufacturing costs. Single step processes take less time and require less complexity and minimize waste relative to other conventional techniques.

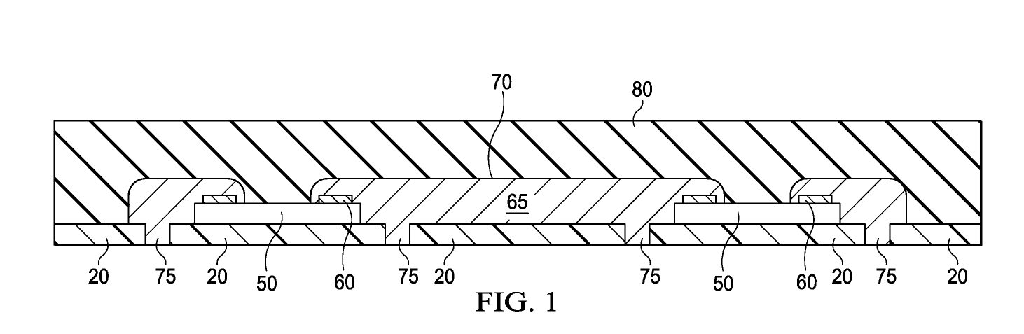

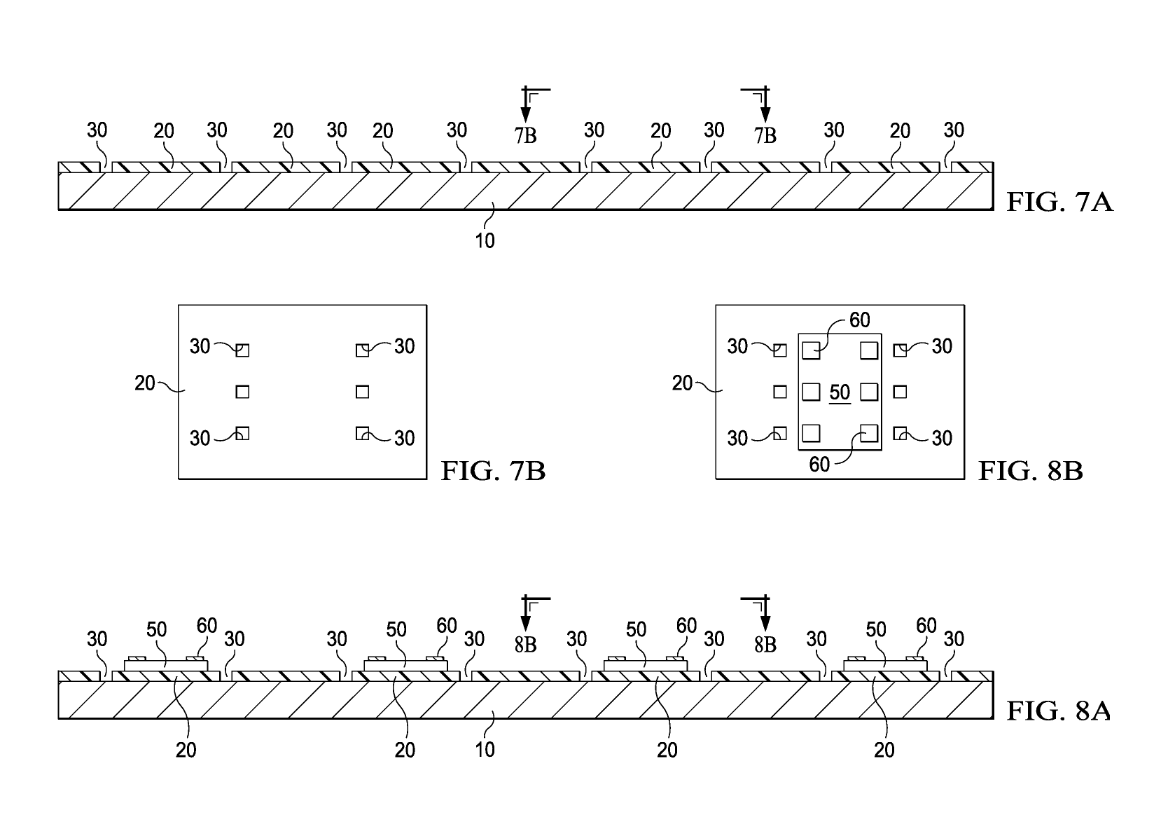

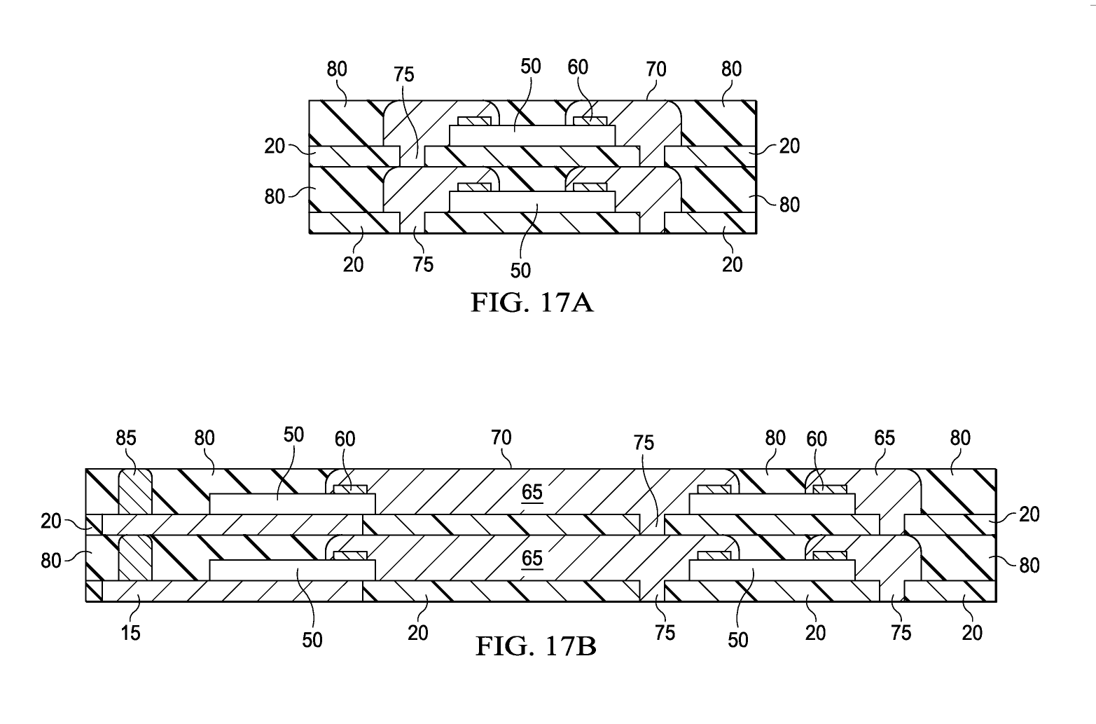

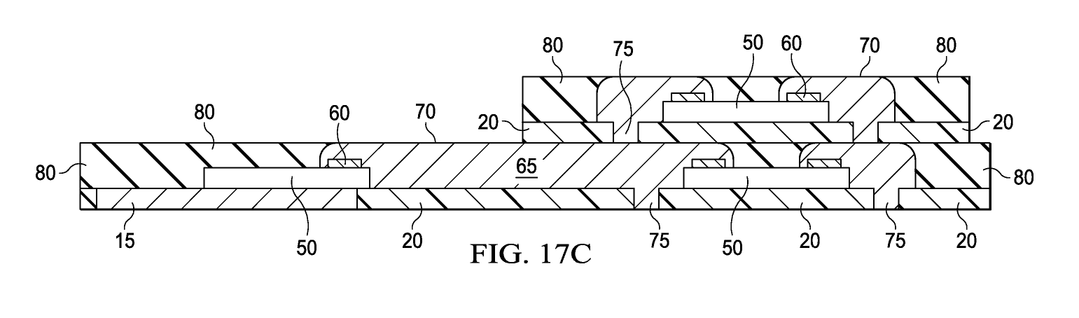

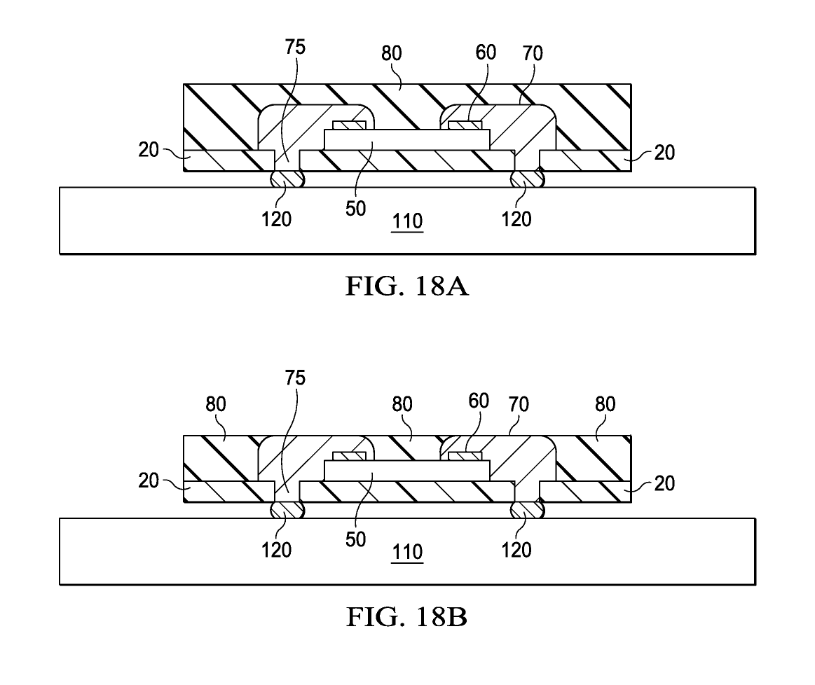

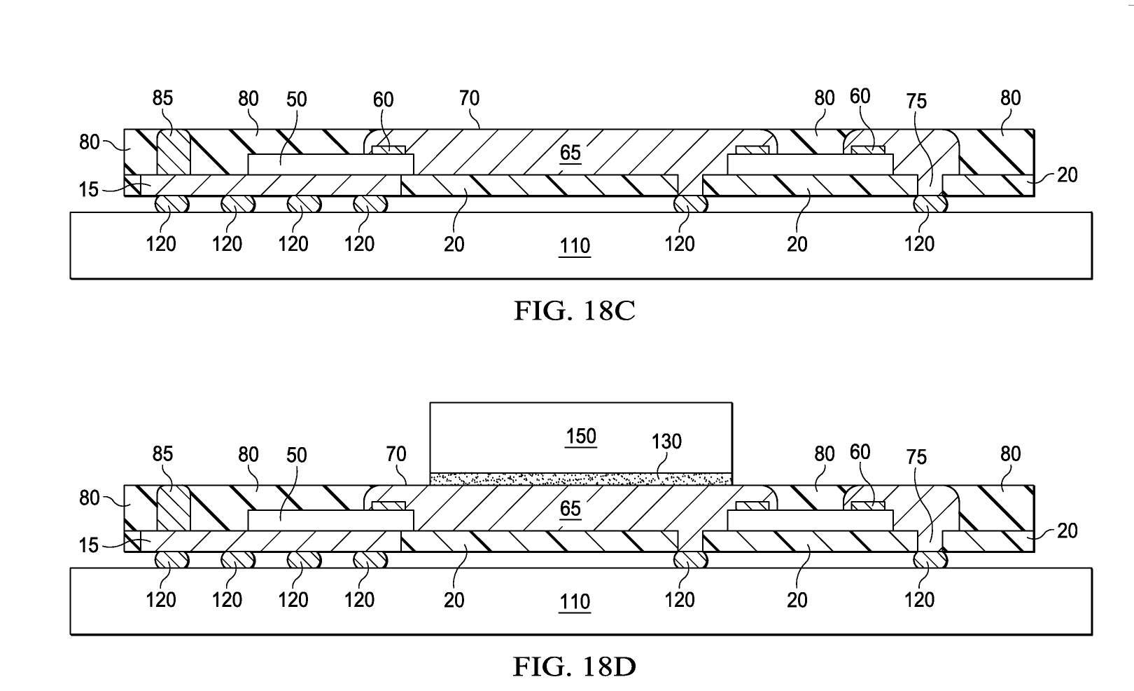

A structural embodiment of a semiconductor package will be described using FIG. 1. Further structural embodiments will be described using FIGS. 17 and 18. A method of fabricating the semiconductor package in accordance with an embodiment of the invention will be described using FIGS. 1-6. Further embodiments of fabricating the semiconductor package will be described using FIGS. 7-11 and FIGS. 12-16.

FIG. 1 illustrates a cross-sectional view of a semiconductor device formed using embodiments of the invention.

Referring to FIG. 1, the semiconductor package comprises a plurality of dies 50 embedded within an encapsulant material 80. The plurality of dies 50 are disposed over a film layer 20 which has openings filled with a conductive material 65 thereby forming through vias 75, which form contact pads for the semiconductor package. The conductive material 65 also forms conductive lines 70 coupling contacts 60 on the plurality of dies 50 with the through vias 75.

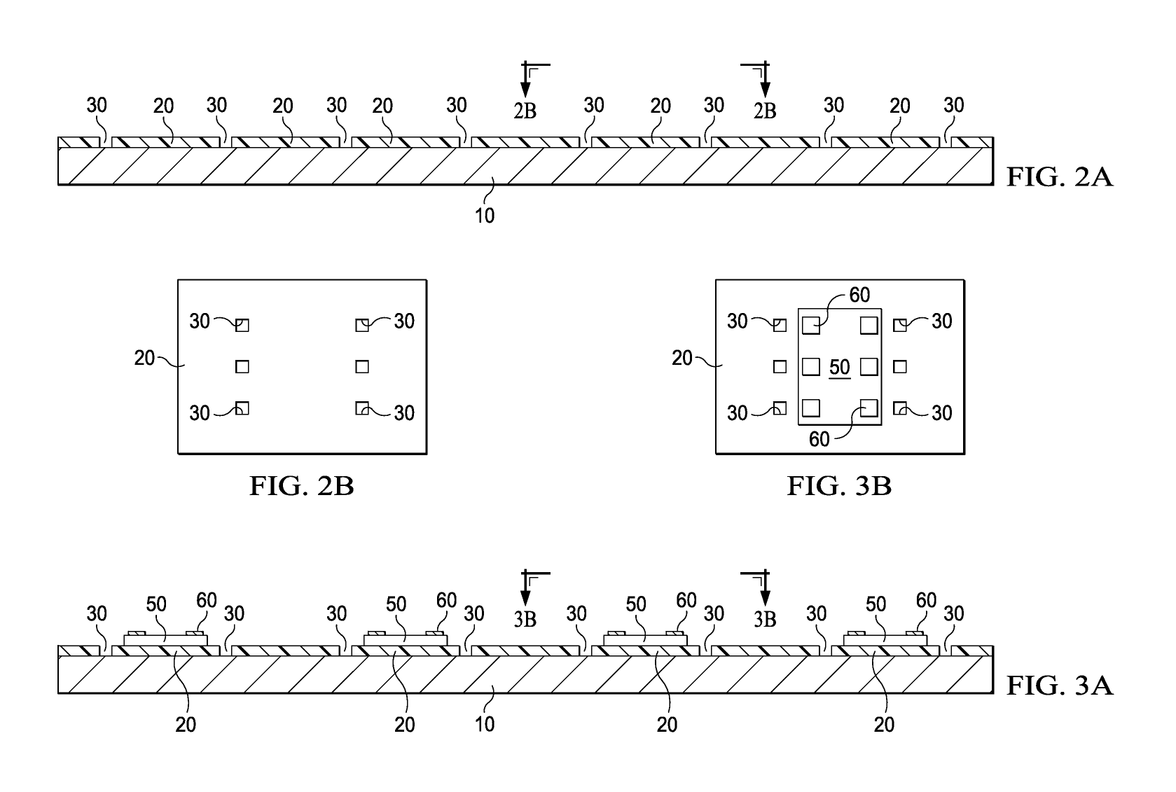

FIG. 2, which includes FIGS. 2A and 2B, illustrates a semiconductor package during fabrication after forming a film layer over a carrier, wherein FIG. 2A illustrates a cross-sectional view and FIG. 2B illustrates a top view.

Referring to FIG. 2A, the semiconductor package is formed using a carrier 10, which provides mechanical support and stability during processing. In various embodiments, the carrier 10 may be a plate made of a rigid material, for example, a metal such as nickel, steel, or stainless steel, a laminate, a film, or a material stack. The carrier 10 may have at least one flat surface over which semiconductor chips may be placed. In one or more embodiments, the carrier 10 may be round or square-shaped although in various embodiments the carrier 10 may be any suitable shape. The carrier 10 may have any appropriate size in various embodiments. In some embodiments, the carrier 10 may include an adhesive tape, for example, a double sided sticky tape laminated onto the carrier 10. The carrier 10 may comprise a frame, which is an annular structure (ring shaped) with an adhesive foil in one embodiment. The adhesive foil may be supported along the outer edges by the frame in one or more embodiments.

A film layer 20 is formed over the carrier 10. The film layer 20 is formed having a pattern such that openings 30 are formed within the film layer 20. In various embodiments, the film layer 20 is formed using a printing, molding, or a lamination process. In one or more embodiments, the film layer 20 and openings 30 are formed in a single step across the carrier 10 without additional patterning. The single step is a process that combines deposition and patterning into one step over the entire carrier 10. As the entire surface of the carrier 10 is processed simultaneously, portions of the carrier 10 are not exposed sequentially, for example, as done in a step and scan lithography tool. Examples of such process include printing, molding, or laminating.

In one embodiment, the film layer 20 is formed using a printing process, for example, using a stencil printing process followed by a heat-treatment process. In other embodiments, other types of printing including screen printing may be used.

In an alternative, the film layer 20 may be formed using a molding process such as compression molding. In one embodiment, a film-assisted molding process may be used. In a film-assisted molding process, a plastic film is sucked down into the inner surfaces of the mold before loading the carrier 10 into the mold cavity. The surface of the mold cavity includes the patterns for the openings 30 within the film layer 20. A molding material is next liquified, and forced into closed mold cavities and held under heat and pressure until all the liquefied mold material is solidified forming the patterned film layer 20. The film layer 20 (e.g., foil) seals the area between the mold tool and certain areas on the carrier 10 or previously applied layers. This keeps those areas free of mold flash (traces of mold material) and—if needed—makes them usable as electrical contacts later. Alternatively, other molding techniques such as injection molding, powder molding, liquid molding may be used to form the film layer 20 having openings 30. After applying the film layer 20, an additional curing process may be performed in various embodiments.

In various embodiments, the film layer 20 comprises a plastic material. In one such embodiment, the film layer 20 comprises parylene, photoresist material, imide, epoxy, duroplast. In alternative embodiments, the film layer 20 comprises silicone, silicon nitride or a ceramic-like material such as silicone-carbon compounds. In one embodiment, the film layer 20 comprises preimpregnated fiber material, which is a combination of a fiber mat, for example, glass or carbon fibers, and a resin, for example, a duroplastic material.

In various embodiments, the film layer 20 has a thickness of about 10 μm to about 50 μm, and about 2 μm to about 10 μm in an alternative embodiment.

FIG. 3, which includes FIGS. 3A and 3B, illustrates a semiconductor package during fabrication after attaching dies over a film layer, wherein FIG. 3A illustrates a cross-sectional view and wherein FIG. 3B illustrates a top view.

Referring to FIG. 3, a plurality of dies 50 or semiconductor chips are attached to the film layer 20. The plurality of dies 50 may be attached using an adhesive in various embodiments. The plurality of dies 50 may include contacts 60 as illustrated. In various embodiments, the adhesive may comprise a glue or other adhesive type material. The adhesive layer is thin to allow subsequent printing processes, for example, less than about 100 μm and between 1 μm to about 50 μm in another embodiment.

In various embodiments, the plurality of dies 50 may comprise any type of die. In various embodiments, the plurality of dies 50 comprise low power chips, for example, chips, which use low currents (e.g., less than 10 amperes). For example, power chips, which draw large currents (e.g., greater than 30 amperes), require thick low conductivity conductive lines and may not be suitable for such packaging as described in embodiments of the invention.

In various embodiments, the plurality of dies 50 may comprise logic, memory, analog, mixed signal chips. Embodiments of the invention also include multiple chips over the film layer 20. For example, two or more chips may be placed between the openings 30.

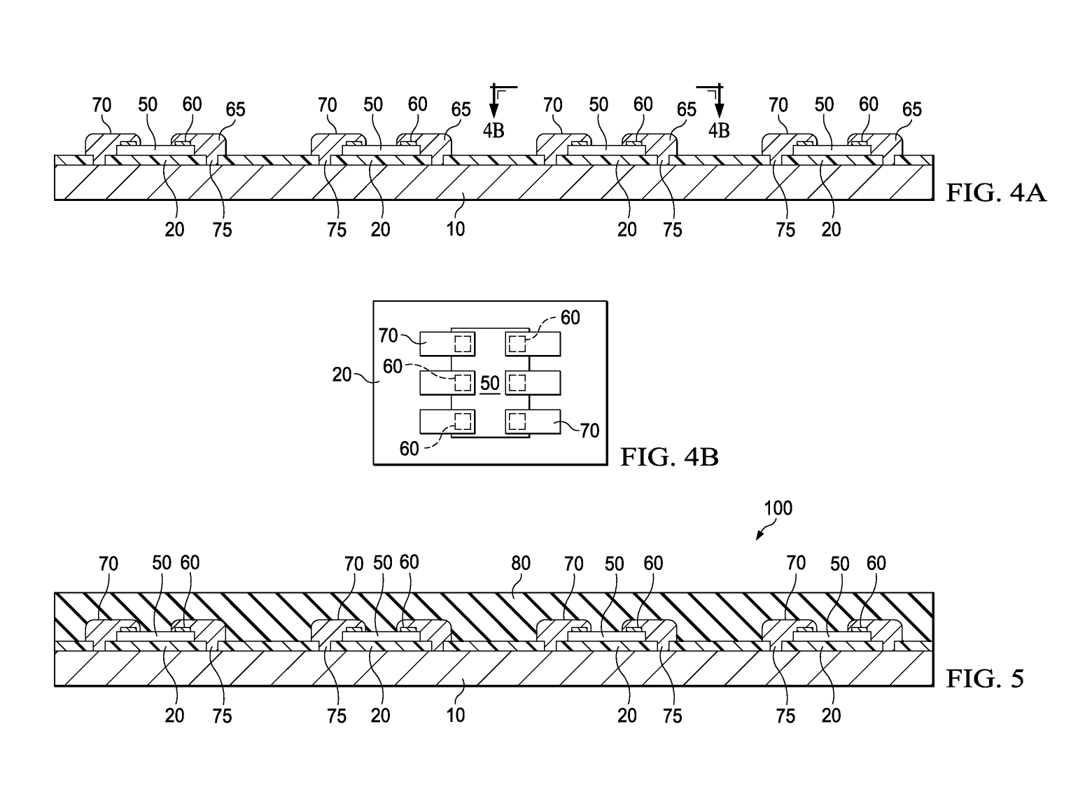

FIG. 4, which includes FIGS. 4A and 4B, illustrates a semiconductor package during fabrication after forming through vias and/or conductive lines, wherein FIG. 4A illustrates a cross-sectional view and wherein FIG. 4B illustrates a top view.

A conductive material 65 is applied over the carrier 10. Advantageously, the conductive material 65 is applied in a single step over the entire carrier 10. For example, the conductive material 65 may be applied without using the complicated steps of patterning, photolithography. Rather, the conductive material 65 may be applied directly using printing, molding, or lamination over the entire carrier 10.

The conductive material 65 may be applied as a liquid, paste, or a solder in various embodiments. In one embodiment, the conductive material 65 may be applied as conductive particles in a polymer matrix so as to form a composite material after curing. In an alternative embodiment, a conductive nano-paste such as a silver nano-paste may be applied. In various embodiments, any suitable conductive material 65 including metals or metal alloys such as aluminum, titanium, gold, silver, copper, palladium, platinum, nickel, chromium or nickel vanadium, may be used to form the conductive material 65.

Advantageously, the conductive paste couples the contacts 60 on the plurality of dies 50 forming conductive lines 70 and through vias 75. Advantageously, both the conductive lines 70 and the through vias 75 may be formed in a single step. Further, multiple conductive lines 70 (for example, interconnecting the dies within the package) are formed simultaneously unlike wire bonding processes which are sequential.

In various embodiments, the conductive material 65 is applied using a printing process, for example, using a stencil printing process followed by a heat-treatment process. In other embodiments, other types of printing including screen printing may be used. In an alternative, the conductive material 65 is applied using a molding process such as compression molding. In one embodiment, film assisted molding may be used to form the conductive material 65. Alternatively, other molding techniques such as injection molding, powder molding, liquid molding may be used to apply the conductive material 65. After applying the conductive material 65, a heat treatment process may be performed to harden and cure the conductive material 65 in various embodiments. Thus, a bottom side of the package being formed comprises a surface of the conductive material 65 and a surface of the film layer 20.

FIG. 5 illustrates a cross-sectional view of a semiconductor package during fabrication after encapsulating the dies.

An encapsulating material 80 is applied over the plurality of dies 50 and the conductive material 65. In various embodiments, the encapsulating material 80 is applied using printing, molding, or lamination over the entire carrier 10. As described above, the encapsulating material 80 may be deposited using stencil printing, film assisted molding in one or more embodiments. The encapsulating material 80 covers the plurality of dies 50.

In various embodiments, the encapsulating material 80 comprises a dielectric material and may comprise a mold compound in one embodiment. In other embodiments, the encapsulating material 80 may comprise a polymer, a biopolymer, a fiber impregnated polymer (e.g., carbon or glass fibers in a resin), a particle filled polymer, and other organic materials. In one or more embodiments, the encapsulating material 80 comprises a sealant not formed using a mold compound, and materials such as epoxy resins and/or silicones. In various embodiments, the encapsulating material 80 may be made of any appropriate duroplastic, thermoplastic, or thermosetting material, or a laminate. The material of the encapsulating material 80 may include filler materials in some embodiments. In one embodiment, the encapsulating material 80 may comprise epoxy material and a fill material comprising small particles of glass or other electrically insulating mineral filler materials like alumina or organic fill materials.

The encapsulating material 80 may be cured, i.e., subjected to a thermal process to harden thus forming a hermetic seal protecting the plurality of dies 50 and the conductive lines 70.

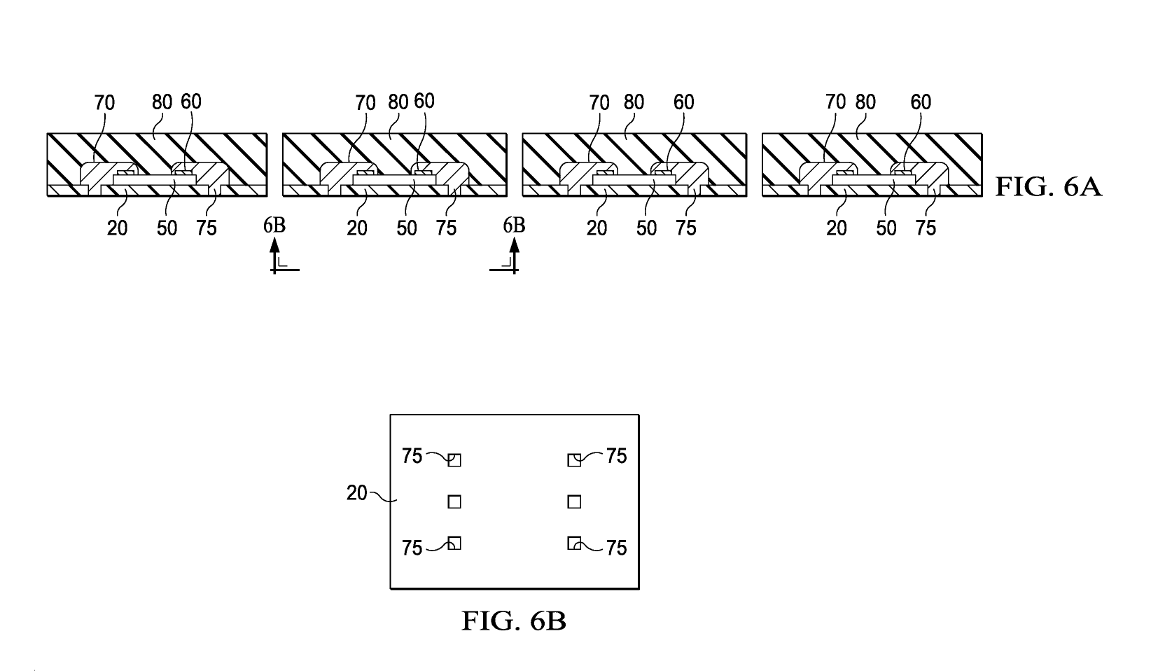

FIG. 6, which includes FIGS. 6A and 6B, illustrates a semiconductor package after singulating the reconfigured wafer into individual packages, wherein FIG. 6A illustrates a cross-sectional view and wherein FIG. 6B illustrates a bottom view.

The hardened encapsulating material 80 is separated from the carrier 10 thereby forming a reconstituted wafer 100. Unlike convention embedded wafer level process, the reconstituted wafer is formed at the end of the processing. The reconstituted wafer 100 is singulated forming individual packages. The bottom of the through vias 75 disposed within the film layer 20 form the external contact pins of the semiconductor package as shown in FIG. 6B. The package may be mounted using these contact pins, for example, as illustrated in FIGS. 17 and 18. No additional lead frame structure and the like is required for contacting the package using embodiments of the invention. In some embodiments, before singulation, the bottom surface of the reconstituted wafer 100 may be subjected to additional plating, e.g., for subsequent soldering.

FIGS. 7-11 illustrates an alternative embodiment of the invention for forming a package on package.

This embodiment follows a similar process to the prior embodiment in FIGS. 7-9. In FIG. 10, unlike the prior embodiment, a thin layer of encapsulant is formed thereby obviating the need for any subsequent thinning processes in forming stackable packages.

FIG. 7, which includes FIGS. 7A and 7B, illustrates a semiconductor package during fabrication after forming a film layer over a carrier, wherein FIG. 7A illustrates a cross-sectional view and wherein FIG. 7B illustrates a magnified top view. As described in the prior embodiment, a film layer 20 is formed over a carrier in a single step over the entire carrier 10.

FIG. 8, which includes FIGS. 8A and 8B, illustrates a semiconductor package during fabrication after attaching dies over the film layer, wherein FIG. 8A illustrates a cross-sectional view and wherein FIG. 8B illustrates a top view. As described in the prior embodiment, a plurality of dies 50 having contacts 60 is attached to the film layer 20 using, for example, a thin adhesive layer.

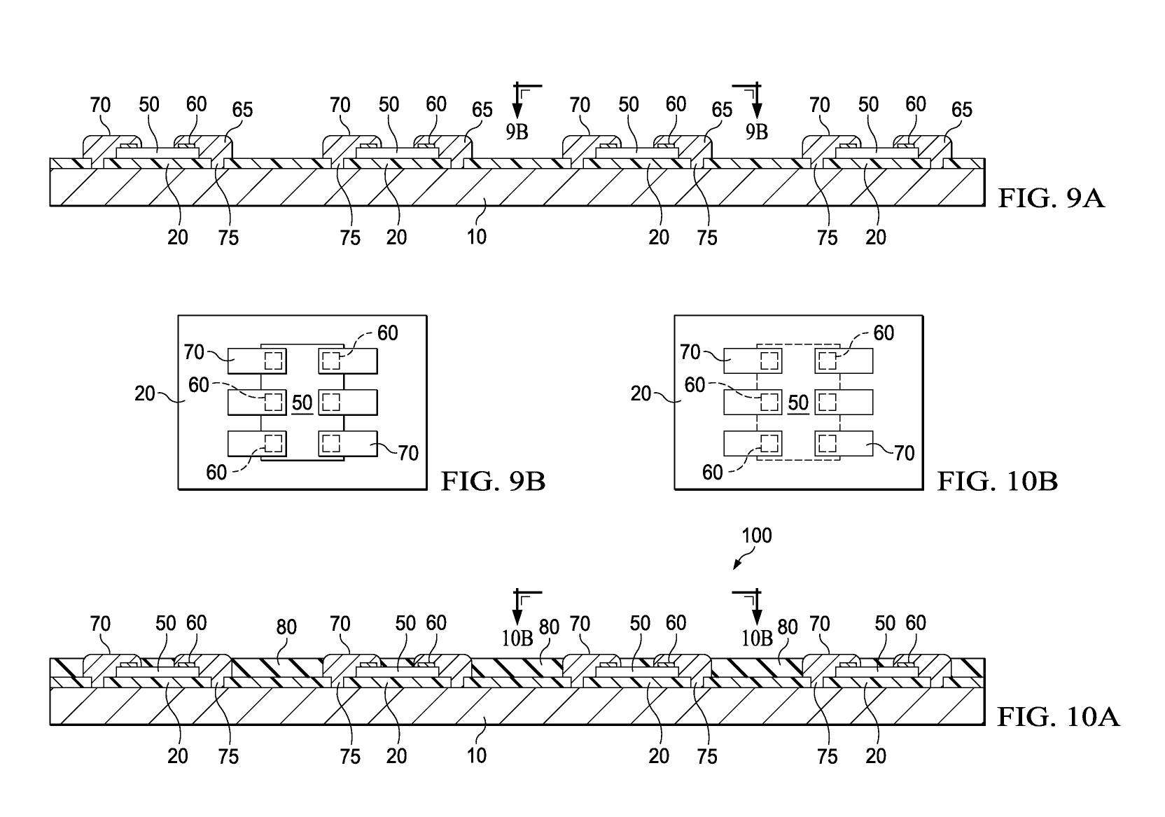

FIG. 9, which includes FIGS. 9A and 9B, illustrates a semiconductor package during fabrication after forming through vias and/or conductive lines, wherein FIG. 9A illustrates a cross-sectional view and wherein FIG. 9B illustrates a top view. Through vias 75 and/or conductive lines 70 are formed in a single step over the entire carrier 10 as described in the prior embodiment.

FIG. 10, which includes FIGS. 10A and 10B, illustrates a semiconductor package during fabrication after encapsulating the dies over the entire carrier, wherein FIG. 10A illustrates a cross-sectional view and wherein FIG. 10B illustrates a top view.

Unlike the prior embodiment, a thin layer of an encapsulating material 80 is formed over the plurality of dies 50. The encapsulating material 80 comprises a thickness of about 100 μm to about 500 μm in various embodiments, and about 100 μm to about 300 μm in one embodiment. Unlike, embedded wafer level processing, where a reconstituted wafer has to support subsequent processing and therefore must be thick, no such constraint exists here because most processing is already finished by this stage. Therefore, in various embodiments, a thin layer of an encapsulating material 80 may be formed without compromising mechanical stability.

In various embodiments, the encapsulating material 80 is applied using printing, molding, or lamination over the entire carrier 10. The encapsulating material 80 covers the plurality of dies 50 but exposes the conductive lines 70.

In various embodiments, as in the prior embodiment, the encapsulating material 80 comprises a dielectric material and may comprise a mold compound in one embodiment. In other embodiments, the encapsulating material 80 may comprise a polymer, a biopolymer, a fiber impregnated polymer (e.g., carbon or glass fibers in a resin), a particle filled polymer, and other organic materials. In one or more embodiments, the encapsulating material 80 comprises a sealant not formed using a mold compound, and materials such as epoxy resins and/or silicones. In various embodiments, the encapsulating material 80 may be made of any appropriate duroplastic, thermoplastic, or thermosetting material, or a laminate. The material of the encapsulating material 80 may include filler materials in some embodiments. In one embodiment, the encapsulating material 80 may comprise epoxy material and a fill material comprising small particles of glass or other electrically insulating mineral filler materials like alumina or organic fill materials.

As described in the prior embodiment, the encapsulating material 80 may be cured forming a reconstituted wafer 100.

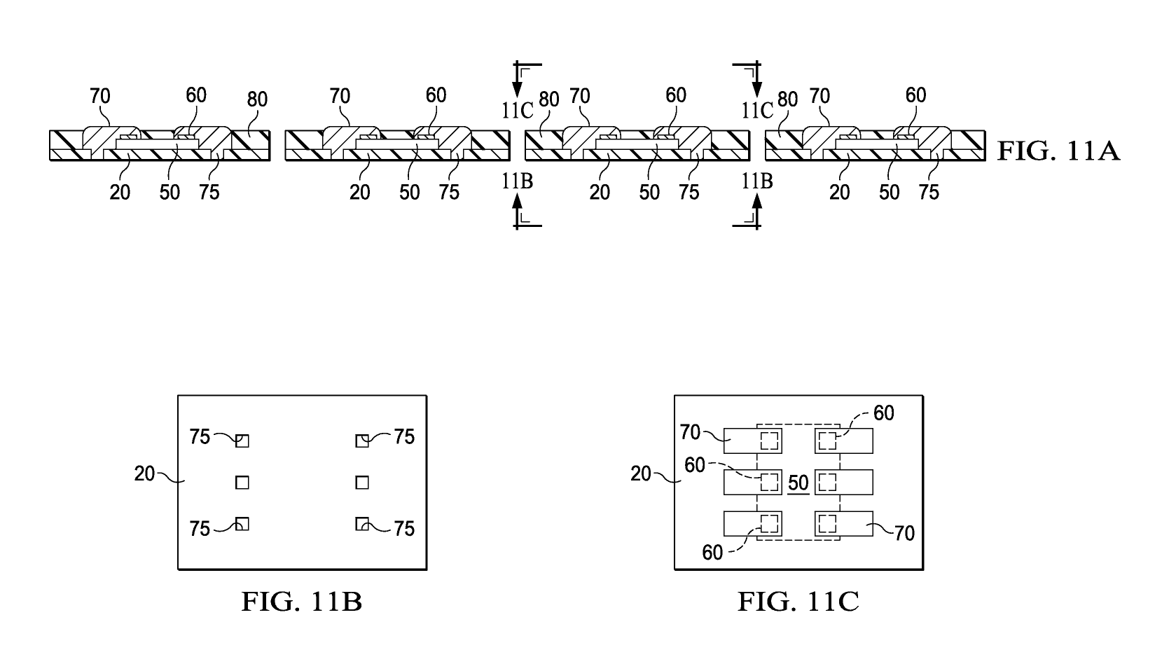

FIG. 11, which includes FIGS. 11A and 11B, illustrates a semiconductor package after singulation, wherein FIG. 11A illustrates a cross-sectional view, wherein FIG. 11B illustrates a bottom view, and wherein FIG. 11C illustrates a top view.

The reconstituted wafer 100 formed in the prior step (FIG. 10) is singulated, as described above, to form individual packages.

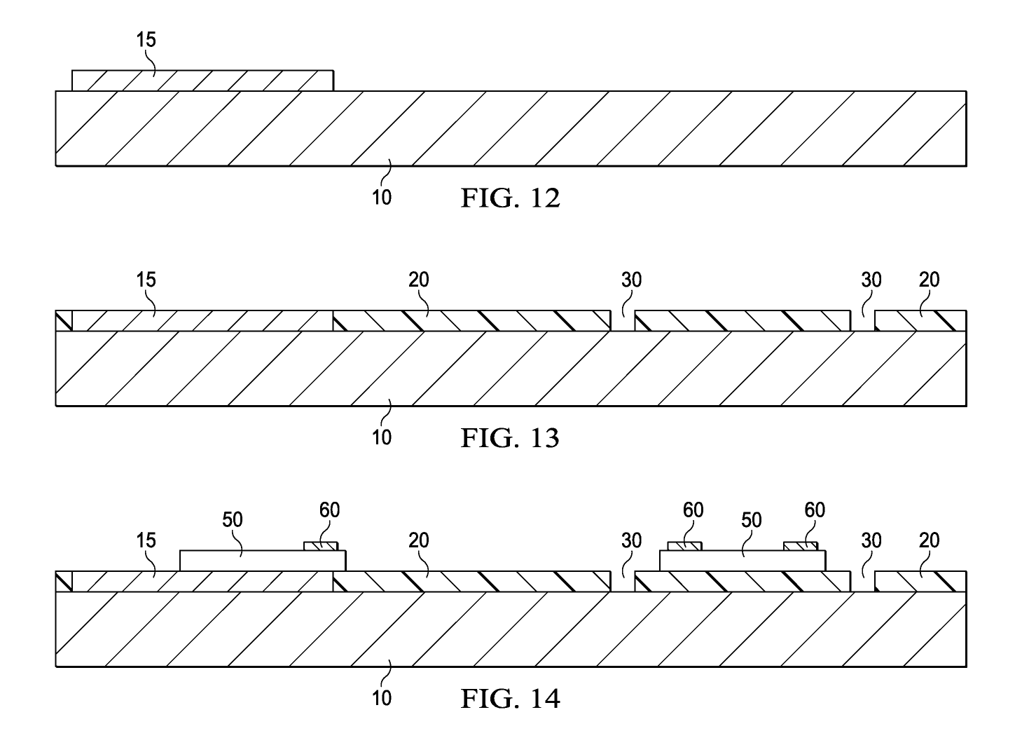

FIGS. 12-16 illustrate an alternative embodiment of forming a semiconductor package comprising multiple chips during fabrication.

This embodiment may include the similar steps as described in the prior embodiments. In addition, in this embodiment, multiple chips are interconnected. Further, one or more of the chips may be contacted from both a front surface and an opposite back surface.

Referring to FIG. 12, a film level interconnect 15 is formed over the entire carrier 10. In various embodiments, a plurality of the film level interconnect 15 is formed over the entire surface of the carrier 10 in a single step. For example, the film level interconnect 15 may be applied without using the complicated steps involving deposition, photolithography, patterning, which also waste material. In various embodiments, the film level interconnect 15 may be applied directly using printing, molding, or lamination.

In one or more embodiments, the film level interconnect 15 may be applied as a liquid, paste, or a solder. In one embodiment, the film level interconnect 15 may be applied as conductive particles in a polymer matrix. In an alternative embodiment, a conductive nano-paste such as a silver nano-paste may be applied. In various embodiments, any suitable material including metals or metal alloys such as aluminum, titanium, gold, silver, copper, palladium, platinum, nickel, chromium or nickel vanadium, may be used to form the film level interconnect 15.

FIG. 13 illustrates a semiconductor package during fabrication after forming a film layer over a carrier. After forming the film level interconnect 15, a film layer 20 is formed over the entire surface of the carrier 10 in a single step. The film level interconnect 15 and the film layer 20 are formed in the same vertical level (laterally adjacent to each other) and may comprise a similar thickness in various embodiments.

FIG. 14 illustrates a semiconductor package during fabrication after attaching dies over the film layer 20. As described in the prior embodiment, a plurality of dies 50 having contacts 60 is attached to the film layer 20 using, for example, a thin adhesive layer. As illustrated in FIG. 14, a die of the plurality of dies 50 may contact one or more of the film level interconnect 15. For example, in FIG. 14, one of the die is coupled from the back side while the other die is not. This may be because one of the dies is a vertical die, e.g., comprising a vertical device such as a discrete vertical transistor. Alternatively, the die may include a vertical circuitry such as a through via coupling the front side to the back side.

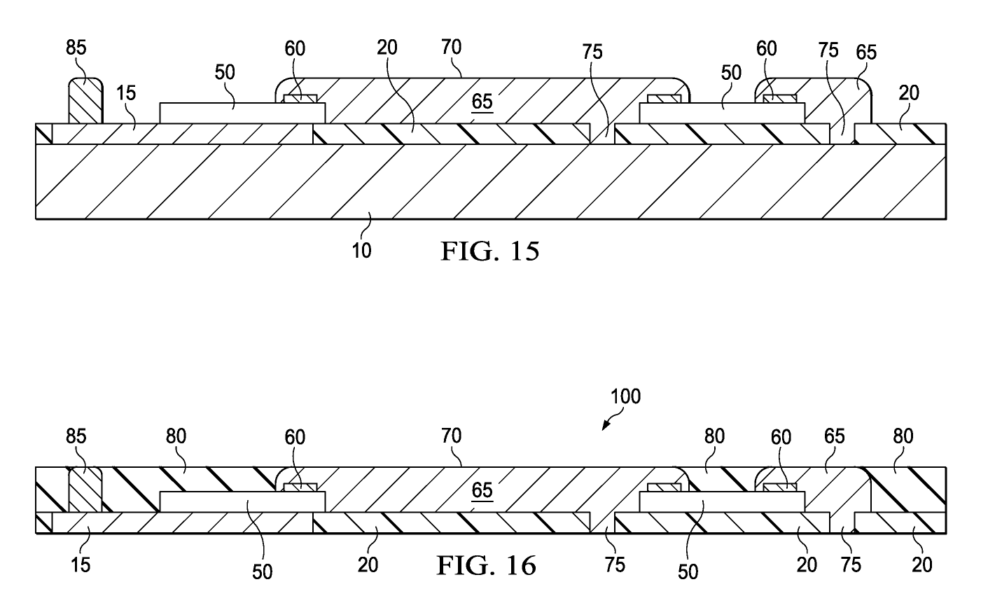

FIG. 15 illustrates a semiconductor package during fabrication after forming through vias and/or conductive lines. Through vias 75 and/or conductive lines 70 are formed as described in the prior embodiment. Additionally a die level interconnect 85 is formed adjacent the plurality of dies 50. The die level interconnects 85 may be coupled to the film level interconnect 15, which couples to the die. Advantageously, the through vias 75, the conductive lines 70, and the die level interconnects 85 are formed simultaneously in a single step, e.g., without additional patterning. In various embodiments, a conductive material may be applied using printing, molding, or lamination to form the through vias 75, the conductive lines 70, and the die level interconnects 85 as described above.

FIG. 16 illustrates a semiconductor package during fabrication after encapsulating the dies. The encapsulation is performed in a single step using a printing, molding, or lamination process described in previous embodiments. The reconfigured wafer formed may be singulated as described above.

FIG. 17, which includes FIGS. 17A-17C, illustrates semiconductor packages formed using embodiments of the invention.

As illustrated in FIG. 17A, the package formed in FIG. 11, may be stacked over each other forming a stacked package. In the illustrated package, the plurality of dies 50 has contact regions (such as contacts 60) on only one side. In an alternative embodiment illustrated in FIG. 17B, a stacked package may be formed using the package of FIG. 16 in which at least one of the dies has contact regions on both sides of the dies. In various embodiments, different types of packages may be stacked using embodiments of the invention. FIG. 17C illustrates such a case in which different types of packages are stacked over each other. Further, embodiments of the invention stacking more than two packages.

FIG. 18, which includes FIGS. 18A-18D, illustrates semiconductor packages formed using embodiments of the invention and mounted over a circuit board.

The semiconductor packages formed using embodiments of the invention may be mounted over a printed circuit board 110 in one embodiment. In one embodiment, the semiconductor package may be arranged face-down on a main surface of the printed circuit board 110. For example, additional solder balls 120 may be formed under the through vias 75 to couple to the printed circuit board 110. In various embodiments, other types of mounting may be used. Further, additional structures may be attached to the semiconductor packages. For example, FIG. 18D illustrates a heat sink 150 disposed over the semiconductor package. The heat sink 150 may be coupled using a thin adhesive 130, which may be thermally conductive allowing heat conduction away from the plurality of dies 50. Embodiments of the invention include combinations of FIGS. 17 and 18.

Embodiments of the invention include flexible packaging, which reduces packaging costs because of the process simplicity. The package thus formed may include multiple chips, multiple components including stacked package configurations. Advantageously, metal layers may be formed over both the front side and an opposite side of the semiconductor chips, which can be used as electrical contact or to conduct heat away from the dies.

Further, advantageously, embodiments of the invention described using FIGS. 2-6, FIGS. 7-11 and FIGS. 12-16 dramatically reduce processing costs and complexity by not using conventional patterning processes. Instead, all features are formed using a wafer like process that forms features within the same unit process module simultaneously (in parallel, unlike sequential processes such as wire bonding) while avoiding sequential wafer level processes such as resist deposition, photolithography, etching resists, and others. Rather, within each unit process module, the features are formed in a single step.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. As an illustration, the embodiments described in FIG. 6 may be combined with the embodiments described in FIGS. 11, 16, 17, and/or 18. Similarly, the processes described in FIGS. 2-6, FIGS. 7-11 and/or FIGS. 12-16 may be combined. It is therefore intended that the appended claims encompass any such modifications or embodiments.

Although the present invention and its advantages have been described in detail, it should be understood that various changes, substitutions and alterations can be made herein without departing from the spirit and scope of the invention as defined by the appended claims. For example, it will be readily understood by those skilled in the art that many of the features, functions, processes, and materials described herein may be varied while remaining within the scope of the present invention.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

1. A semiconductor package comprising:
a first die disposed over a film layer;
an encapsulant material surrounding the first die and disposed over the film layer; and
a first interconnect having a first end and an opposite second end, the first end contacting a contact on the first die and the second end forming a first external contact pin of the semiconductor package, the first external contact pin being disposed within the film layer, wherein the first interconnect comprises a conductive material disposed continuously between the first and the second ends and having a first exposed surface at the first end and a second exposed surface at the second end.

2. The package of claim 1, further comprising:
a second die disposed over the film layer and embedded in the encapsulant; and
a second interconnect having a first end, a second end, and a third end, the first end coupling the contacts on the first die, the second end coupling contacts on the second die, the third end forming a second external contact pin of the semiconductor package, wherein the second external contact pin is disposed within the film layer.

3. The package of claim 2, wherein the first and the second external pins share a common surface with a surface of the film layer.

4. The package of claim 1, wherein the conductive material comprising a resin filled with conductive particles.

5. The package of claim 1, wherein the conductive material comprises a composite material having conductive particles in a polymer matrix.

6. The package of claim 1, wherein the first interconnect comprises a hardened metal paste.

7. The package of claim 1, wherein the first interconnect comprises a cured silver nano paste.

8. A method of forming a semiconductor package, the method comprising:
using a first common deposition and patterning step, applying a film layer over a carrier, the film layer having through openings;
attaching a back side of a semiconductor chip to the film layer, the semiconductor chip having contacts on a front side;
using a second common deposition and patterning step, forming a conductive material within the openings, the conductive material contacting the contacts;
forming a reconfigured wafer by encapsulating the semiconductor chip, the film layer, and the conductive material in an encapsulant; and
singulating the reconfigured wafer to form a plurality of packages.

9. The method of claim 8, further comprising removing the carrier.

10. The method of claim 8, wherein the first common deposition and patterning step comprises printing, molding, or laminating.

11. The method of claim 8, wherein the second common deposition and patterning step comprises printing, molding, or laminating.

12. The method of claim 8, wherein the first and the second common deposition and patterning steps comprises printing.

13. The method of claim 12, wherein the printing comprises screen printing.

14. The method of claim 8, wherein the first and the second common deposition and patterning steps comprises molding.

15. The method of claim 14, wherein the molding comprises film assisted molding process.

16. The method of claim 8, wherein after encapsulating the semiconductor chip, a surface of the conductive material on a top side of the reconfigured wafer forms a contact pad and a surface of the conductive material in the through openings forms external contacts pins on a bottom side of the reconfigured wafer.

17. The method of claim 8, wherein forming a reconfigured wafer comprises forming a contact pad on a top side of the reconfigured wafer in a single step.

18. The method of claim 17, further comprising stacking a first package of the plurality of packages over a second package of the plurality of packages.

19. The method of claim 17, further comprising stacking a first package of the plurality of packages under a second package different from the first package, the first and the second packages coupled through the contact pad.

20. The method of claim 8, wherein forming a conductive material comprises applying a conductive paste comprising a resin with metal particles.

21. A method of forming a semiconductor package, the method comprising:
using a first common deposition and patterning step, applying a patterned conductive layer over a carrier;
using a second common deposition and patterning step, applying a film layer over the carrier and laterally adjacent the patterned conductive layer, the film layer having through openings;
attaching a back side of a semiconductor chip to the film layer, the semiconductor chip having front contacts on a front side;
using a third common deposition and patterning step, forming a conductive material within the openings, the conductive material contacting the front contacts of the semiconductor chip and the patterned conductive layer;
using a fourth common deposition and patterning step, forming a reconfigured wafer by encapsulating the semiconductor chip, the film layer, and the conductive material in an encapsulant; and
singulating the reconfigured wafer.

22. The method of claim 21, wherein the semiconductor chip has back contacts on the back side, the back contacts contacting the patterned conductive layer.

23. The method of claim 21, wherein the first common deposition and patterning step comprises printing, molding, or laminating.

24. The method of claim 21, wherein the first common deposition and patterning step comprises screen printing.

25. The method of claim 21, wherein the first common deposition and patterning step comprises film assisted molding.

26. The method of claim 21, wherein the second common deposition and patterning step comprises screen printing.

27. The method of claim 21, wherein the second common deposition and patterning step comprises film assisted molding.

28. The method of claim 21, wherein the third and the fourth common deposition and patterning steps comprises printing, molding, or laminating.
